(19) United States
(12) Patent Application Publication
(10) Pub. No.: US 2014/0363932 A1
(43) Pub. Date: Dec. 11, 2014

(54) ZINC TARGET INCLUDING FLUORINE, METHOD OF FABRICATING ZINC NITRIDE THIN FILM BY USING THE SAME, AND METHOD OF FABRICATING THIN FILM TRANSISTOR BY USING THE SAME

(71) Applicant: Samsung Electronics Co., Ltd., Suwon-Si (KR)

(72) Inventors: Myung-kwan RYU, Yongin-si (KR); Tae-sang KIM, Seoul (KR); Hyun-suk KIM, Hwaseong-si (KR); Joon-seok PARK, Yongin-si (KR); Young-soo PARK, Yongin-si (KR)

(73) Assignee: SAMSUNG ELECTRONICS CO., LTD., Suwon-Si (KR)

(21) Appl. No.: 14/187,889

(22) Filed: Feb. 24, 2014

(30) Foreign Application Priority Data
Jun. 10, 2013 (KR) 10-2013-0066067

(51) Int. Cl. H01L 29/66; C23C 14/34

(52) U.S. Cl. CPC H01L 29/66742; C23C 14/3414
USPC 438/149; 204/298.13; 204/192.15

(57) ABSTRACT

Provided are fluorine-containing zinc targets, methods of fabricating a zinc oxynitride thin film by using the zinc targets, and methods of fabricating a thin film transistor by using the zinc oxynitride thin film. The methods include mounting a fluorine-containing zinc target and a substrate in a sputtering chamber, supplying nitrogen gas and inert gas into the sputtering chamber, and forming a fluorine-containing zinc oxynitride thin film on the substrate.

### CROSS-REFERENCE TO RELATED APPLICATIONS

This application claims priority under 35 U.S.C. §119 to Korean Patent Application No. 10-2013-0066067, filed on Jun. 10, 2013, in the Korean Intellectual Property Office, the disclosure of which is incorporated herein in its entirety by reference.

### BACKGROUND

1. Field

The present disclosure relates to methods of fabricating a zinc nitride thin film including an impurity and/or methods of fabricating a channel of a thin film transistor.

2. Description of Related Art

Thin film transistors (TFTs) are used in various fields. For example, TFTs may be used as switching devices and/or driving devices in the field of displays, and may be used as a selection switch in cross-point type memory devices.

An amorphous silicon thin film TFT (a-Si TFT) may be used as a driving and/or switching device in a display. This device may be uniformly formed on a large substrate having a size of over 2 m×2 m at a low cost and is currently widely used. However, due to the tendency towards large and high definition of display, high performance devices are also desired. Thus, the existing a-Si TFT having a mobility of 0.5 cm²/Vs is believed to be a limit. Accordingly, there is a need to develop a high performance TFT having a mobility greater than that of the a-Si TFT and/or a method of fabricating the TFT.

A polycrystalline silicon TFT (poly-Si TFT) may have a performance that is much higher than the a-Si TFT. Poly-Si TFTs may have a mobility in a range from a few tens to a few hundreds cm²/Vs, and thus, may have a performance that may be applied to a high definition display that may not be realized with the a-Si TFT. Also, the poly-Si TFT may have less degradation of device characteristics than the a-Si TFT. However, fabricating the poly-Si TFT may require a more complicated process compared to that of the a-Si TFT, and accordingly, fabricating cost is increased. Although the poly-Si TFT may be applied to a high definition display or an OLED, the poly-Si TFT may be disadvantageous from a cost standpoint. In the case of the poly-Si TFT, due to technical problems, such as the limitation of fabricating equipment and non-uniformity of product quality, currently, it is not easy to apply the poly-Si TFT to a fabricating process that uses a large substrate having a size of over 1 m. Thus, it may be difficult to apply the poly-Si TFT to TV products.

Accordingly, there is a need to develop a TFT having both the strong points of the a-Si TFT and the poly-Si TFT. Studies on this matter have been actively conducted, and, as a representative product, a Zn compound TFT has been disclosed. Recently, the Zn compound TFT has drawn attention, and in order to fabricate the Zn compound TFT that includes an impurity, a co-sputtering method using a target including the impurity and a Zn target is used together is used.

However, a method of fabricating a thin film by using the co-sputtering with plural targets may be complicated and may have low productivity.

### SUMMARY

Example embodiments relate to methods of fabricating a Zn nitride thin film that includes an impurity by using a single Zn target that includes an impurity.

Example embodiments also relate to methods of fabricating a thin film transistor including the Zn nitride thin film that includes an impurity as the channel layer.

Additional aspects will be set forth in part in the description which follows and, in part, will be apparent from the description, or may be learned by practice of example embodiments.

According to example embodiments, a fluorine-containing zinc target includes a body. The body includes a mixture of zinc fluoride powder and zinc powder. The body may be a sintered body of the zinc fluoride power and the zinc powder.

In example embodiments, the fluorine-containing zinc target may include fluorine in a range from about 0.1 atom % to about 10 atom %.

In example embodiments, the target may further include zinc nitride powder in the body.

In example embodiments, the target may further include zinc oxide powder in the body.

According to example embodiments, a method of fabricating a zinc nitride thin film by using a single target sputtering includes: mounting a fluorine-containing zinc target and a substrate in a sputtering chamber; supplying nitrogen gas and inert gas into the sputtering chamber; and forming a fluorine-containing zinc nitride thin film on the substrate.

In example embodiments, the fluorine-containing zinc target may be a body including a mixture of zinc powder and zinc fluoride powder.

In example embodiments, the fluorine-containing zinc target may include fluorine in a range from about 0.1 atom % to about 10 atom %.

In example embodiments, the fluorine-containing zinc target may further include at least one of zinc nitride powder and zinc oxide powder in the body.

In example embodiments, the fluorine-containing zinc nitride film may include zinc in a range from about 40 atom % to about 60 atom %, oxygen in a range from about 0 atom % to about 10 atom %, nitrogen in a range from about 30 atom % to about 40 atom %, and fluorine in a range from about 0.1 atom % to about 10 atom %.

In example embodiments, the method may further include supplying oxygen gas into the sputtering chamber together with the supplying nitrogen gas and inert gas into the sputtering chamber, and the forming the fluorine-containing zinc nitride thin film may include forming a fluorine-containing zinc oxynitride thin film. In example embodiments, the zinc oxynitride thin film may have a thickness in a range from about 5 nm to about 100 nm.

According to example embodiments, a method of fabricating a thin film transistor (TFT) that includes a channel, a gate electrode, a source electrode, and a drain electrode on a substrate, includes: mounting a fluorine-containing zinc target and a substrate in a sputtering chamber; supplying nitrogen gas and inert gas into the sputtering chamber; forming a fluorine-containing zinc nitride thin film on the substrate; and forming the channel by patterning the fluorine-containing zinc nitride thin film.

According to example embodiments, a method of fabricating a thin film includes forming a zinc nitride thin film containing fluorine on a substrate facing a zinc target containing fluorine in a sputtering chamber using a single-target sputtering process. The single-target sputtering process includes supplying inert gas into the sputtering chamber. The single-target sputtering process may include supplying nitrogen gas into the sputtering chamber if the zinc target containing fluorine does not contain nitrogen.

In example embodiments, the forming the zinc nitride thin film containing fluorine includes holding the zinc target containing fluorine using a holder in the sputtering chamber and arranging the substrate in the sputtering chamber on a susceptor in the sputtering chamber. The susceptor may be below the holder.

The forming the zinc nitride thin film containing fluorine may include at least one of maintaining a pressure in the sputtering chamber in a range from about 10⁻⁶ Pa to about 1 Pa, maintaining the substrate or the susceptor at a temperature of 250° C. or less, and discharging a gas from the sputtering chamber using a vacuum pump.

In example embodiments, the forming the zinc nitride thin film containing fluorine may include maintaining the temperature of the substrate at 250° C. or less, maintaining the pressure in the sputtering chamber at 0.4 Pa; forming a fluorine-containing zinc oxynitride thin film by supplying oxygen gas into the sputtering chamber; applying a power of 300 W to the fluorine-containing zinc target; supplying the nitrogen gas into the sputtering chamber; supplying the argon gas into the sputtering chamber as the inert gas; supplying the oxygen gas, the nitrogen gas, and the argon gas into the sputtering chamber in a volume ratio of Ar:N₂:O₂ of 150:100:10; and using a single zinc target that includes fluorine in the range of about 1 atom % to about 10 atom % as the zinc target containing fluorine.

In example embodiments, the zinc target containing fluorine may be a body including a mixture of zinc powder and zinc fluoride powder. The zinc target containing fluorine may further include zinc nitride (Zn₃N₂) powder in the body. The zinc target containing fluorine may further include zinc oxide powder in the body.

In example embodiments, the method may further include supplying a fluorine-containing gas into the sputtering chamber.

In example embodiments, the forming the zinc nitride thin film containing fluorine may include forming a fluorine-containing zinc oxynitride thin film by one of: supplying oxygen gas into the sputtering chamber together with supplying the nitrogen gas and the inert gas into the sputtering chamber; supplying oxygen gas into the sputtering chamber together with supplying the inert gas into the sputtering chamber if the zinc target containing fluorine also contains nitrogen; and supplying the inert gas into the sputtering chamber if the zinc target containing fluorine also contains nitrogen and oxygen.

In example embodiments, a method of fabricating a thin film transistor (TFT) includes forming a zinc nitride thin film containing fluorine on the substrate using one of the above-described methods; and forming a channel by patterning the zinc nitride thin film containing fluorine. The TFT may include the channel, a gate electrode, a source electrode, and a drain electrode on the substrate. The gate electrode may be one of on the channel and between the channel and the substrate. The source electrode and the drain electrode may be spaced apart from each other on the substrate. The source electrode and the drain electrode may be connected to two ends of the channel, respectively.

### BRIEF DESCRIPTION OF THE DRAWINGS

These and/or other aspects will become apparent and more readily appreciated from the following description of non-limiting embodiments, as illustrated in the accompanying drawings in which like reference characters refer to like parts throughout the different views. The drawings are not necessarily to scale, emphasis instead being placed upon illustrating the features of example embodiments. In the drawings:

FIG. 1 is a schematic cross-sectional view of a sputtering apparatus according to example embodiments;

FIG. 2 is a cross-sectional view of a fluorine-containing zinc nitride thin film according to example embodiments;

FIGS. 3A through 3G are cross-sectional views showing a method of fabricating a thin film transistor (TFT) by using a fluorine-containing zinc oxynitride thin film or a fluorine-containing zinc nitride thin film as a channel, according to example embodiments;

FIGS. 4A through 4E are cross-sectional views showing a method of fabricating a top-gate type TFT by using a fluorine-containing zinc oxynitride thin film or a fluorine-containing zinc nitride thin film as a channel, according to example embodiments; and

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

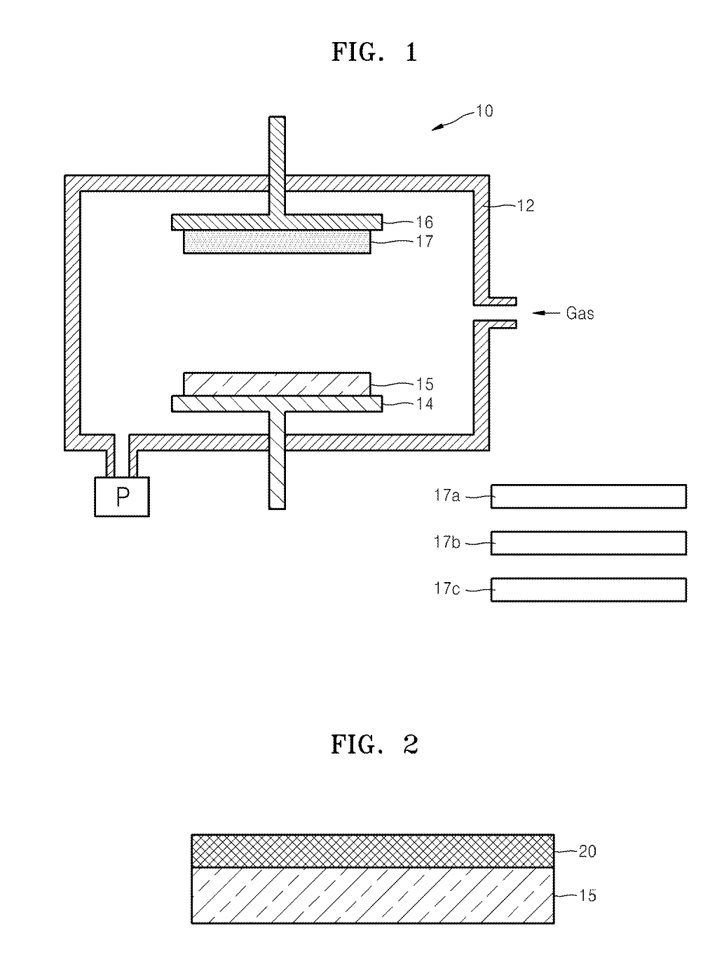

FIG. 1 is a schematic cross-sectional view of a sputtering apparatus 10 according to example embodiments.

Referring to FIG. 1, a sputtering apparatus 10 may include a susceptor 14 and a target holder 16 in a sputtering chamber 12. A substrate 15 may be disposed on the susceptor 14. The target holder 16 may hold a target 17. The susceptor 14 may be rotated by a driving unit (not shown). An inert gas may be supplied from outside through a side of the sputtering chamber 12. The inert gas may be argon gas. In the description below, an example of using argon gas as the inter gas is described, but example embodiments are not limited thereto. Other units that supply other gases, for example, oxygen gas, nitrogen gas, or fluorine-containing gas, into the sputtering chamber 12 may be connected to the sputtering chamber 12. As described later, the target 17 may be a zinc target that includes fluorine 17a, a zinc target that includes fluorine and nitrogen 17b, or a zinc target that includes fluorine, nitrogen, and oxygen 17c.

The sputtering chamber 12 may be maintained at a desired (and/or alternatively predetermined) process pressure. The process pressure may be in a range from about 10⁻⁶ Pa to about 1 Pa, inclusive, but is not limited thereto. The substrate 15 or the susceptor 14 may be maintained at a temperature of 250° C. or less, a temperature in the range of 250° C. to 25° C., or at room temperature, but is not limited thereto.

A vacuum pump P for discharging a gas from the sputtering chamber 12 may be connected to another side of the sputtering chamber 12.

FIG. 2 is a cross-sectional view of a fluorine-containing zinc nitride thin film 20 according to example embodiments.

Referring to FIG. 2, the fluorine-containing zinc nitride thin film 20 may be formed on the substrate 15. The fluorine-containing zinc nitride thin film thin film 20 may be a fluorine-containing zinc oxynitride thin film that further includes oxygen.

The fluorine-containing zinc nitride thin film 20 (and/or fluorine-containing zinc oxynitride thin film) may be formed to have a thickness in a range from about 10 nm to about 100 nm. The fluorine-containing zinc nitride thin film 20 may include zinc in a range from about 40 atom % to about 60 atom %, nitrogen in a range from about 30 atom % to about 40 atom %, and fluorine in a range from about 0.1 atom % to about 10 atom %. A sum of the amount of zinc, nitrogen, and fluorine in the fluorine-containing zinc nitride thin film 20 may be less than or equal to 100 atom %. The fluorine-containing zinc oxynitride thin film 20 may include zinc in a range from about 40 atom % to about 60 atom %, oxygen in a range from about 0 atom % to about 10 atom %, nitrogen in a range from about 30 atom % to about 40 atom %, and fluorine in a range from about 0.1 atom % to about 10 atom %. A sum of the amount of zinc, nitrogen, oxygen, and fluorine in the fluorine-containing zinc oxynitride thin film 20 may be less than or equal to 100 atom %.

Referring to FIGS. 1 and 2, a method of fabricating a zinc nitride thin film by using a single target sputtering process, according to example embodiments, is described.

First, a zinc target 17a that includes fluorine may be prepared. The zinc target 17a may include fluorine in a range from about 0.1 atom % to about 10 atom %. The zinc target 17a that includes fluorine may be formed by sintering a mixture formed by mixing zinc powder and zinc fluoride (ZnF₂) powder.

A zinc target 17b may be formed by including nitrogen. The zinc target 17b that includes nitrogen and fluorine may be prepared by sintering a mixture formed by mixing zinc powder, ZnF₂ powder, and zinc nitride (Zn₃N₂) powder. The zinc target 17b may include fluorine in a range from about 0.1 atom % to about 10 atom %.

Also, a zinc target 17c that includes nitrogen, fluorine, and oxygen may be prepared. The zinc target 17c that includes nitrogen, fluorine, and oxygen may be formed by sintering a mixture formed by mixing zinc powder, ZnF₂ powder, Zn₃N₂ powder, and zinc oxide powder. The zinc target 17c may include fluorine in a range from about 0.1 atom % to about 10 atom %.

Next, the substrate 15 for sputtering may be disposed on the susceptor 14, and one of the zinc targets 17a to 17c may be held by the target holder 16. The substrate 15 may face the one of the zinc targets 17a to 17c held by the target holder 16. The substrate 15 may be a glass substrate, a plastic substrate, or a semiconductor substrate. However, example embodiments are not limited thereto and the substrate 15 may be one of various substrates that are used in a general semiconductor device process.

When the fluorine-containing zinc nitride thin film 20 is formed by using the zinc target that includes fluorine 17a, nitrogen gas may be supplied into the sputtering chamber 12 together with argon gas in a ratio in accordance with the composition of the thin film 20 to be fabricated. Also, fluorine-containing gas may also be supplied to the sputtering chamber 12 to adjust the fluorine concentration of the fluorine-containing zinc nitride thin film 20. The fluorine-containing gas may be NF₃ or SF₆ besides fluorine gas.

When the fluorine-containing zinc nitride thin film 20 is fabricated as a fluorine-containing zinc oxynitride thin film 20 using the zinc target that includes fluorine 17a, oxygen gas may be further supplied into the sputtering chamber 12. Also, fluorine-containing gas may be supplied to the sputtering chamber 12 to adjust the fluorine concentration of the fluorine-containing zinc oxynitride thin film. The fluorine-containing gas may be NF₃ or SF₆ besides fluorine gas.

When the fluorine-containing zinc nitride thin film 20 is fabricated by using the zinc target that includes nitrogen and fluorine 17b, argon gas may be supplied into the sputtering chamber 12. Also, in order to adjust the concentrations of nitrogen and fluorine in the fluorine-containing zinc nitride thin film 20, nitrogen-containing gas and fluorine-containing gas may be supplied into the sputtering chamber 12. The fluorine-containing gas may be NF₃ or SF₆ besides fluorine gas. The nitrogen-containing gas may be nitrogen gas, but is not limited thereto.

When the fluorine-containing zinc oxynitride thin film 20 is fabricated by using the zinc target that includes nitrogen and fluorine 17b, argon gas and oxygen gas may be supplied into the sputtering chamber 12. Also, in order to adjust the concentrations of nitrogen and fluorine in the fluorine-containing zinc oxynitride thin film 20, nitrogen-containing gas and fluorine-containing gas may be supplied into the sputtering chamber 12. The fluorine-containing gas may be NF₃ or SF₆ besides fluorine gas. The nitrogen-containing gas may be nitrogen gas, but is not limited thereto.

When the fluorine-containing zinc oxynitride thin film 20 is fabricated by using the zinc target that includes nitrogen, fluorine, and oxygen 17c, argon gas may be supplied into the sputtering chamber 12. Also, in order to adjust the concentrations of nitrogen, oxygen, and fluorine in the fluorine-containing zinc oxynitride thin film 20, nitrogen-containing gas, oxygen gas, and fluorine-containing gas may be supplied into the sputtering chamber 12. The fluorine-containing gas may be NF₃ or SF₆ besides fluorine gas. The nitrogen-containing gas may be nitrogen gas, but is not limited thereto.

The fluorine-containing zinc nitride thin film 20 (and/or fluorine-containing zinc oxynitride thin film) may be formed to have a thickness in a range from about 10 nm to about 100 nm, but is not limited thereto. The fluorine-containing zinc nitride thin film 20 may include zinc in a range from about 40 atom % to about 60 atom %, nitrogen in a range from about 30 atom % to about 40 atom %, and fluorine in a range from about 0.1 atom % to about 10 atom %. A sum of the amount of zinc, nitrogen, and fluorine in the fluorine-containing zinc nitride thin film 20 may be less than or equal to 100 atom %. The fluorine-containing zinc oxynitride thin film 20 may include zinc in a range from about 40 atom % to about 60 atom %, oxygen in a range from about 0 atom % to about 10 atom %, nitrogen in a range from about 30 atom % to about 40 atom %, and fluorine in a range from about 0.1 atom % to about 10 atom %. A sum of the amount of zinc, nitrogen, oxygen, and fluorine in the fluorine-containing zinc oxynitride thin film 20 may be less than or equal to 100 atom %.

A process condition for fabricating the fluorine-containing zinc oxynitride thin film 20 by using the zinc target that includes fluorine 17a will be described. The temperature of the substrate 15 is maintained at 250° C. or less or at room temperature by controlling the temperature of the susceptor 14. The single zinc target that includes fluorine 17a may include fluorine in a range from about 1 atom % to about 10 atom %. Also, Ar, N₂, and O₂ may be supplied into the sputtering chamber 12 in a volume ratio of Ar:N₂:O₂=150:100:10. A process pressure in the sputtering chamber 12 may be maintained at 0.4 Pa. A power of 300 W may be applied to the zinc target that includes fluorine 17a.

According to example embodiments, a zinc target that includes fluorine 17a may be used, a zinc target that includes fluorine and nitrogen 17b may be used, or a zinc target that includes fluorine, nitrogen, and oxygen 17c may be used. However, example embodiments are not limited thereto. For example, the fluorine-containing zinc oxynitride thin film 20 may be formed by supplying fluorine-containing gas into the sputtering chamber 12 while using a zinc target that does not include fluorine. The fluorine-containing gas may be NF₃ or SF₆ besides fluorine gas.

According to example embodiments, a method of fabricating a fluorine-containing zinc nitride thin film, and/or a fluorine-containing zinc oxynitride thin film may use a single target sputtering method instead of a co-sputtering method in which two targets are used. Thus, a method of fabricating a fluorine-containing zinc nitride thin film, and/or a fluorine-containing zinc oxynitride thin film may be simplified and may have higher productivity compared to a co-sputtering method in which two targets are used.

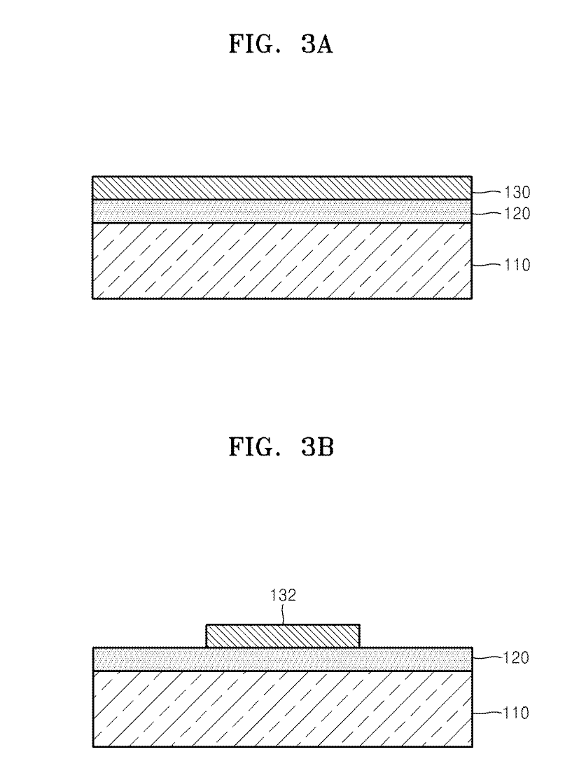

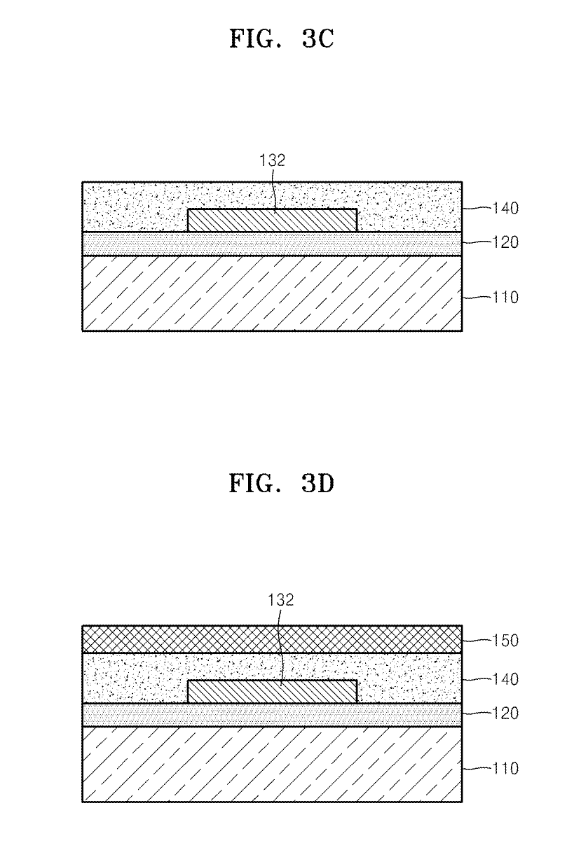

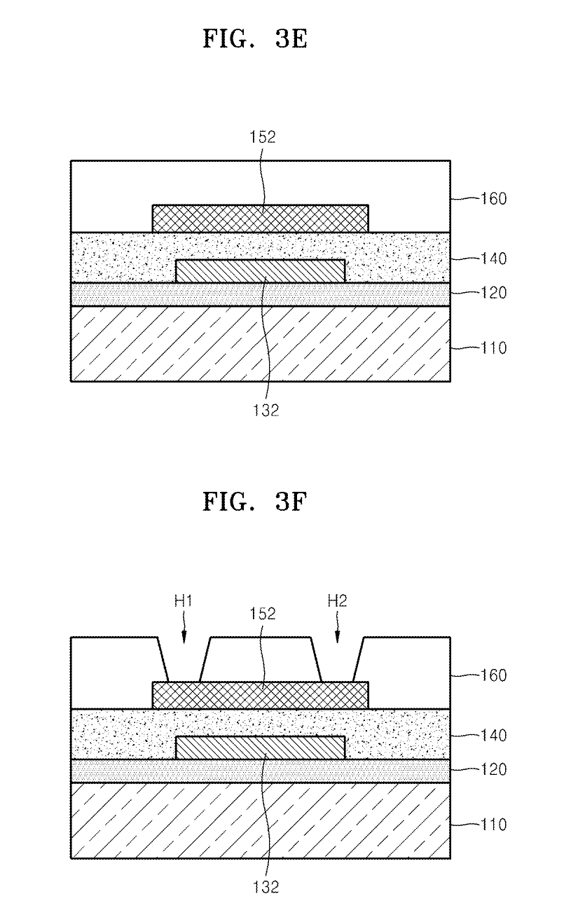

FIGS. 3A through 3G are cross-sectional views showing a method of fabricating a TFT by using a fluorine-containing zinc oxynitride thin film or a fluorine-containing zinc nitride thin film as a channel, according to example embodiments.

Referring to FIG. 3A, a substrate 110 is prepared. The substrate 110 may be formed of silicon, glass, or an organic material. A barrier layer 120 may be formed on the substrate 110. The barrier layer 120 may block penetration of impurities from the substrate 110. The barrier layer 120 may be formed of silicon nitride. A light-blocking film may further be formed between the substrate 110 and the barrier layer 120. The light-blocking film may be a metal film.

A conductive material layer 130 is formed on the barrier layer 120. The conductive material layer 130 may include a metal such as Ti, Pt, Ru, Au, Ag, Mo, Al, W, Cu, and an alloy thereof, and/or a conductive oxide such as InZnO (IZO) and AlZnO (AZO).

Referring to FIG. 3B, a gate electrode 132 is formed by patterning the conductive material layer 130.

Referring to FIG. 3C, a gate insulating layer 140 is formed by patterning an insulating material that is coated on the gate electrode 132. The gate insulating layer 140 may include silicon oxide. Alternatively, the gate insulating layer 140 may include a material having a higher dielectric constant than silicon oxide, such as silicon nitride, hafnium (Hf) oxide, and aluminum oxide.

Referring to FIG. 3D, a thin film 150 may be formed on the gate insulating layer 140 by using a reactive sputtering method, based on one of the above-described single target sputtering methods according to example embodiments with reference to FIGS. 1 and 2. The thin film 150 may include a fluorine containing zinc oxynitride thin film, or a fluorine containing zinc nitride thin film.

Referring to FIGS. 1 and 3D, the thin film 150 may be formed by disposing the substrate 110 on the susceptor 14 in the sputtering chamber 12 after the gate insulating layer 140 has been formed on the substrate 110. In other words, the stacked structure in FIG. 3C that includes the gate insulating layer 140 on the substrate 110 may correspond to the substrate 15 in FIG. 1. Next, a zinc target that includes fluorine 17a may be mounted on the target holder 16, and a single-target sputtering process using the zinc target that includes fluorine 17a may be used to form the thin film 150. Argon gas, oxygen gas, and nitrogen gas may be supplied into the sputtering chamber 12 during the single-target sputtering process. Alternatively, if the thin film 150 is formed as a zinc nitride film that includes fluorine using the zinc target that includes fluorine 17a, oxygen gas may be omitted from being supplied into the sputtering chamber 12.

The zinc target that includes fluorine 17a may include fluorine in a range from about 0.1 atom % to about 10 atom %. The method of forming the zinc target that includes fluorine 17a is described above with reference to FIG. 1.

The thin film 150 may be formed to have a thickness in a range from about 10 nm to about 100 nm. The thin film 150 may include zinc in a range from about 40 atom % to about 60 atom %, oxygen in a range from about 0 atom % to about 10 atom %, nitrogen in a range from about 30 atom % to about 40 atom %, and fluorine in a range from about 0.1 atom % to about 10 atom %. A sum of the amount of zinc, nitrogen, oxygen, and fluorine in the thin film 150 may be less than or equal to 100 atom %. The thin film 150 that has 0 atom % of oxygen is a zinc nitride thin film that does not include oxygen in the thin film 150.

Instead of forming the thin film 150 using the zinc target that includes fluorine 17a, the thin film 150 may be formed using a zinc target that includes fluorine and nitrogen 17b, or the thin film 150 may be formed using a zinc target that includes fluorine, nitrogen and oxygen 17c. The zinc target that includes fluorine and nitrogen 17b, and the zinc target that includes fluorine, nitrogen, and oxygen 17c are described above with reference to FIGS. 1 and 2. If the zinc target that includes fluorine and nitrogen 17b is used instead of the zinc target that includes fluorine 17a to form the thin film 150, then nitrogen gas may be omitted from being supplied to the sputtering chamber 12 when the thin film 150 is formed. If the zinc target that includes fluorine, nitrogen, and oxygen 17c is used instead of the zinc target that includes fluorine 17a to form the thin film 150, then nitrogen gas and/or oxygen gas may be omitted from being supplied to the sputtering chamber 12 when the thin film 150 is formed.

When the thin film 150 as a channel-forming film is formed as a fluorine-containing zinc nitride film, oxygen may be omitted from being supplied to the sputtering chamber 12 during the reactive sputtering method.

Referring to FIG. 3E, a channel 152 may be formed by patterning the thin film 150 to correspond to the gate electrode 132. An etch stop layer 160 covering the channel 152 may be formed on the gate insulating layer 140. The etch stop layer 160 may include at least one of silicon oxide, silicon nitride, and an organic insulating material.

Referring to FIG. 3F, first and second contact holes H1 and H2 may be formed in the etch stop layer 160. The first and second contact holes H1 and H2 may be formed to respectively expose first and second regions of the channel 152. The first region of the channel 152 may be an edge of the channel 152 or an adjacent region thereof, and the second region may be the other edge of the channel 152 or an adjacent region thereof.

Referring to FIG. 3G, a source electrode 171 and a drain electrode 172 may be formed on the etch stop layer 160. The source electrode 171 and the drain electrode 172 may be respectively connected to the first and second regions of the channel 152 that are exposed by the first and second contact holes H1 and H2. The source electrode 171 and the drain electrode 172 may be or may not be formed of the same material as the gate electrode 132. The source electrode 171 and the drain electrode 172 may be formed as a single layer or multi-layers. The source electrode 171 and the drain electrode 172 may be formed by forming a conductive layer on the etch stop layer 160 and patterning (etching) the conductive layer. When the patterning (etching) is performed, the etch stop layer 160 may protect a channel 152 between the source electrode 171 and the drain electrode 172. However, the formation of the etch stop layer 160 may be omitted.

A protective film 180 covering the source electrode 171 and the drain electrode 172 may be formed on the etch stop layer 160. The protective film 180 may include and at least one of silicon nitride, silicon oxide, alumina, and an organic material, such as resin. As a result, a bottom gate type TFT 100 according to example embodiments may be formed.

Additionally, an annealing process may further be performed by using a furnace, a rapid thermal annealing, a laser, or a hot plate.

The bottom gate type TFT 100 may be applied to a driving transistor in liquid crystal displays (LCDs) or organic light-emitting diode (OLED) displays, or a transistor that constitutes a peripheral circuit of a memory device.

When a fluorine-containing zinc oxynitride thin film or fluorine-containing zinc nitride thin film is fabricated, a single target sputtering method may be used, and thus, the process may be simplified and productivity may be increased. Also, a TFT fabricated in this way may have a high ion mobility, and an on/off ratio of the TFT may be increased.

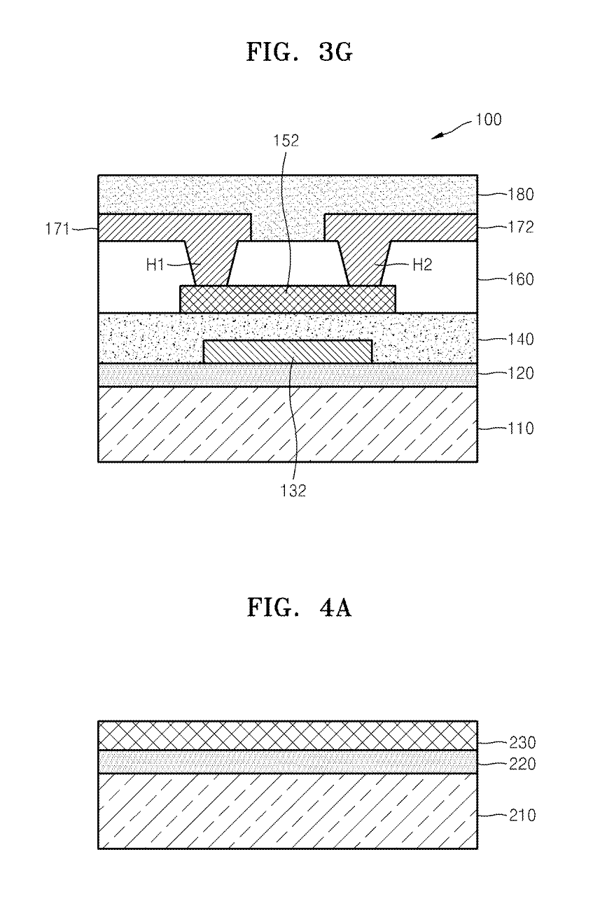

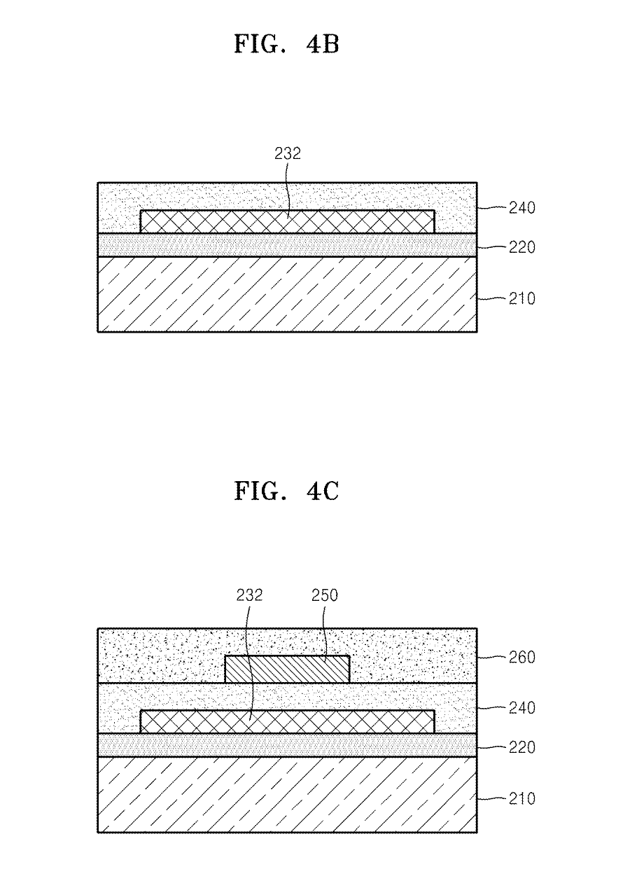

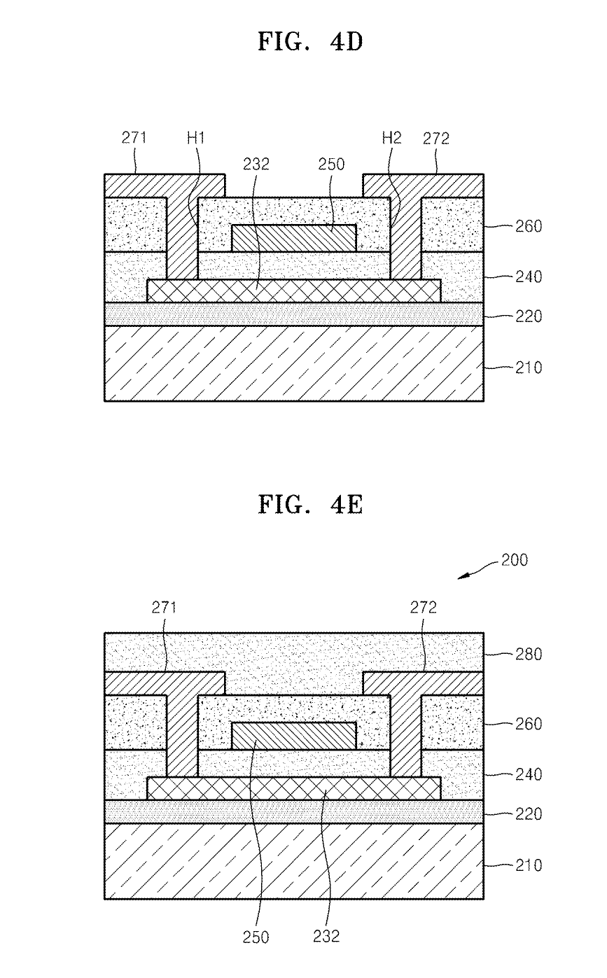

FIGS. 4A through 4E are cross-sectional views showing a method of fabricating a top gate type thin film transistor (TFT) by using a fluorine-containing zinc oxynitride thin film or a fluorine-containing zinc nitride thin film as a channel, according to example embodiments.

Referring to FIG. 4A, a substrate 210 is prepared. The substrate 210 may be formed of Si, glass, or an organic material. A barrier layer 220 may be formed on the substrate 210. The barrier layer 220 may block the penetration of impurities from the substrate 210. The barrier layer 220 may be formed of silicon nitride. A light-blocking film may further be formed between the substrate 210 and the barrier layer 220. The light-blocking film may be a metal film. A thin film 230 may be formed on the barrier layer 220 by using a reactive sputtering method, based on one of the above-described single target sputtering methods according to example embodiments. The thin film 230 may include a fluorine containing zinc oxynitride thin film, or a fluorine containing zinc nitride thin film For the formation of the thin film 230, the substrate 210 having the barrier layer 220 thereon may be disposed on a susceptor (14 in FIG. 1) in a sputtering chamber (12 in FIG. 1) and a zinc target (17 in FIG. 1) including fluorine may be mounted on a target holder (16 in FIG. 1). Argon gas, oxygen gas, and nitrogen gas are supplied into the sputtering chamber 22. Alternatively, if the thin film 230 is formed as a zinc nitride film that includes fluorine using the zinc target that includes fluorine 17a, oxygen gas may be omitted from being supplied into the sputtering chamber 12.

The zinc target 17a including fluorine may include fluorine in a range from about 0.1 atom % to about 10 atom %. The method of forming the fluorine-containing zinc target 17a is the same as described above, and thus, the description thereof is not repeated.

The thin film 230 may be formed to have a thickness in a range from about 5 nm to about 100 nm (and/or from about 10 nm to about 100 nm). The thin film 230 may include zinc in a range from about 40 atom % to about 60 atom %, oxygen in a range from about 0 atom % to about 10 atom %, nitrogen in a range from about 30 atom % to about 40 atom %, and fluorine in a range from about 0.1 atom % to about 10 atom %. A sum of the amount of zinc, nitrogen, oxygen, and fluorine in the thin film 230 may be less than or equal to 100 atom %. The thin film 230 that has 0 atom % of oxygen is a zinc nitride thin film that does not include oxygen in the thin film 230.

Instead of forming the thin film 230 using the zinc target that includes fluorine 17a, the thin film 230 may be formed using a zinc target that includes fluorine and nitrogen 17b, or the thin film 230 may be formed using a zinc target that includes fluorine, nitrogen and oxygen 17c. The zinc target that includes fluorine and nitrogen 17b, and the zinc target that includes fluorine, nitrogen, and oxygen 17c are described above with reference to FIGS. 1 and 2. If the zinc target that includes fluorine and nitrogen 17b is used instead of the zinc target that includes fluorine 17a to form the thin film 230, then nitrogen gas may be omitted from being supplied to the sputtering chamber 12 when the thin film 150 is formed. If the zinc target that includes fluorine, nitrogen, and oxygen 17c is used instead of the zinc target that includes fluorine 17a to form the thin film 230, then nitrogen gas and/or oxygen gas may be omitted from being supplied to the sputtering chamber 12 when the thin film 230 is formed.

When the thin film 230 is formed as a fluorine-containing zinc nitride film, oxygen may be omitted from being supplied to the sputtering chamber 12 during the reactive-sputtering method.

Referring to FIG. 4B, the thin film 230 may be patterned into a channel 232. A gate insulating layer 240 is formed on the channel 232. The gate insulating layer 240 may be formed of silicon oxide. Alternatively, the gate insulating layer 240 may include a material having a higher dielectric constant than silicon oxide, such as silicon nitride, hafnium (Hf) oxide, or aluminum oxide.

Referring to FIG. 4C, after forming a conductive material layer using a metal, an alloy, a conductive metal oxide, or a conductive metal nitride on the gate insulating layer 240, the conductive material layer is patterned to form a gate electrode 250.

An insulating interlayer 260 covering the gate electrode 250 is formed on the gate insulating layer 240.

Referring to FIG. 4D, first and second contact holes H1 and H2 that expose both edges of the channel 232 are formed by sequentially etching the insulating interlayer 260 and the gate insulating layer 240.

After coating a conductive material that fills the first and second contact holes H1 and H2 on the interlayer insulating layer 260, a source electrode 271 and a drain electrode 272 are formed by patterning the conductive material.

Referring to FIG. 4E, a protective film 280 covering the source electrode 271 and the drain electrode 272 may be formed on the insulating interlayer 260. The protective film 280 may be formed of silicon nitride, silicon oxide, alumina, or an organic material, such as resin. As a result, a top gate type TFT 200 is formed.

According to the above-described method of fabricating the TFT, a single target sputtering method is used, thus, the method is simplified and productivity is increased, compared to a co-sputtering method in which two zinc targets are used. Also, a TFT fabricated in this way has high ion mobility, and an on/off ratio of the TFT may be increased.

It should be understood that example embodiments described herein should be considered in a descriptive sense only and not for purposes of limitation. Descriptions of features or aspects within each embodiment should typically be considered as available for other similar features or aspects in other embodiments.

While some example embodiments have been particularly shown and described, it will be understood by one of ordinary skill in the art that variations in form and detail may be made therein without departing from the spirit and scope of the claims.

What is claimed is:

1. A fluorine-containing sputtering zinc target comprising:
a body including a mixture of zinc fluoride powder and zinc powder.

2. The fluorine-containing sputtering zinc target of claim 1, wherein the fluorine-containing zinc target includes fluorine in a range from about 0.1 atom % to about 10 atom %.

3. The fluorine-containing sputtering zinc target of claim 1, further comprising:
zinc nitride powder in the body.

4. The fluorine-containing sputtering zinc target of claim 3, further comprising:
zinc oxide powder in the body.

5. A method of fabricating a zinc nitride thin film by using a single target sputtering, the method comprising:
preparing a fluorine-containing zinc target;
mounting the fluorine-containing zinc target and a substrate in a sputtering chamber;
supplying nitrogen gas and inert gas into the sputtering chamber; and
forming a fluorine-containing zinc nitride thin film on the substrate.

6. The method of claim 5, wherein the preparing of the fluorine-containing zinc target includes sintering a body including a mixture of zinc powder and zinc fluoride powder.

7. The method of claim 6, wherein the fluorine-containing zinc target includes fluorine in a range from about 0.1 atom % to about 10 atom %.

8. The method of claim 6, wherein the mixture further includes at least one of zinc nitride powder and zinc oxide powder.

9. The method of claim 6, wherein the fluorine-containing zinc nitride film includes zinc in a range from about 40 atom % to about 60 atom %, oxygen in a range from about 0 atom % to about 10 atom %, nitrogen in a range from about 30 atom % to about 40 atom %, and fluorine in a range from about 0.1 atom % to about 10 atom %.

10. The method of claim 9, further comprising:
supplying oxygen gas into the sputtering chamber together with the supplying nitrogen gas and inert gas into the sputtering chamber,
wherein the forming the fluorine-containing zinc nitride thin film includes forming a fluorine-containing zinc oxynitride thin film.

11. The method of claim 9, wherein the zinc oxynitride thin film has a thickness in a range from about 5 nm to about 100 nm.

12. A method of fabricating a thin film transistor (TFT), the TFT including a channel, a gate electrode, a source electrode, and a drain electrode on a substrate, the method comprising:
preparing a fluorine-containing zinc target;
mounting the fluorine-containing zinc target and a substrate in a sputtering chamber;
supplying nitrogen gas and inert gas into the sputtering chamber;
forming a fluorine-containing zinc nitride thin film on the substrate; and
forming the channel by patterning the fluorine-containing zinc nitride thin film.

13. The method of claim 12, wherein the preparing of the fluorine-containing zinc target includes sintering a body including a mixture of zinc powder and zinc fluoride powder.

14. The method of claim 13, wherein the fluorine-containing zinc target includes fluorine in a range from about 0.1 atom % to about 10 atom %.

15. The method of claim 13, wherein the mixture further includes at least one of zinc nitride powder and zinc oxide powder.

16. The method of claim 13, further comprising:
supplying oxygen gas into the sputtering chamber together with the supplying nitrogen gas and inert gas into the sputtering chamber,
wherein the forming the fluorine-containing zinc nitride thin film includes forming a fluorine-containing zinc oxynitride thin film.

17. The method of claim 16, wherein the fluorine-containing zinc nitride thin film includes zinc in a range from about 40 atom % to about 60 atom %, oxygen in a range from about 0 atom % to about 10 atom %, nitrogen in a range from about 30 atom % to about 40 atom %, and fluorine in a range from about 0.1 atom % to about 10 atom %.

18. The method of claim 16, wherein the zinc oxynitride thin film has a thickness in a range from about 5 nm to about 100 nm.

19. A method of fabricating a thin film, the method comprising:
forming a zinc nitride thin film containing fluorine on a substrate facing a zinc target containing fluorine in a sputtering chamber using a single-target sputtering process,
the single-target sputtering process including supplying inert gas into the sputtering chamber, and
the single-target sputtering process including supplying nitrogen gas into the sputtering chamber if the zinc target containing fluorine does not contain nitrogen.

20. The method of claim 19, wherein
the forming the zinc nitride thin film containing fluorine includes holding the zinc target containing fluorine using a holder in the sputtering chamber,
the forming the zinc nitride thin film containing fluorine includes arranging the substrate in the sputtering chamber on a susceptor in the sputtering chamber,
the susceptor is below the holder, and
the forming the zinc nitride thin film containing fluorine includes at least one of:
maintaining a pressure in the sputtering chamber in a range from about 10⁻⁶ Pa to about 1 Pa,
maintaining the substrate or the susceptor at a temperature of 250° C. or less, and
discharging a gas from the sputtering chamber using a vacuum pump.

21. The method of claim 19, wherein the forming the zinc nitride thin film containing fluorine includes:
maintaining the temperature of the substrate at 250° C. or less,
maintaining the pressure in the sputtering chamber at 0.4 Pa,
forming a fluorine-containing zinc oxynitride thin film by supplying oxygen gas into the sputtering chamber,
applying a power of 300 W to the fluorine-containing zinc target,
supplying the nitrogen gas into the sputtering chamber,
supplying argon gas into the sputtering chamber as the inert gas,
supplying the oxygen gas, the nitrogen gas, and the argon gas into the sputtering chamber in a volume ratio of Ar:N₂:O₂ of 150:100:10, and
using a single zinc target that includes fluorine in the range of about 1 atom to about 10 atom % as the zinc target containing fluorine.

22. The method of claim 19, wherein the forming the fluorine-containing zinc nitride thin film further includes:
supplying a fluorine-containing gas into the sputtering chamber.

23. The method of claim 19, wherein the forming the zinc nitride thin film containing fluorine includes forming a fluorine-containing zinc oxynitride thin film by one of:
supplying oxygen gas into the sputtering chamber together with supplying the nitrogen gas and the inert gas into the sputtering chamber,
supplying oxygen gas into the sputtering chamber together with supplying the inert gas into the sputtering chamber if the zinc target containing fluorine also contains nitrogen, and
supplying the inert gas into the sputtering chamber if the zinc target containing fluorine also contains nitrogen and oxygen.
